(19) United States
(12) Patent Application Publication
(10) Pub. No.: US 2022/0415627 A1
(43) Pub. Date: Dec. 29, 2022

(54) PLASMA PROCESSING APPARATUS AND SUBSTRATE SUPPORT

(71) Applicant: Tokyo Electron Limited, Tokyo (JP)

(72) Inventors: Ryota NISHI, Miyagi (JP); Akira ISHIKAWA, Miyagi (JP); Genki HIRATA, Miyagi (JP)

(73) Assignee: Tokyo Electron Limited, Tokyo (JP)

(21) Appl. No.: 17/848,596

(22) Filed: Jun. 24, 2022

(30) Foreign Application Priority Data
Jun. 25, 2021 (JP) 2021-105368

(51) Int. Cl. H01J 37/32

(52) U.S. Cl. CPC H01J 37/32724; H01J 37/32449

(57) ABSTRACT

There is provided a plasma processing apparatus comprising: a plasma processing container; and a substrate support disposed in the plasma processing container and having a support surface on an upper portion of a base. The substrate support includes: a heat transfer gas supply hole configured to supply a heat transfer gas from the base side to the support surface; a first member disposed on the support surface side in the heat transfer gas supply hole and made of silicon carbide; a second member disposed under the first member in the heat transfer gas supply hole and made of a porous resin; and a third member disposed under the second member in the heat transfer gas supply hole and made of polytetrafluoroethylene (PTFE).

### CROSS-REFERENCE TO RELATED APPLICATIONS

This application claims priority to Japanese Patent Application No. 2021-105368 filed on Jun. 25, 2021, the entire contents of which are incorporated herein by reference.

### TECHNICAL FIELD

The present disclosure relates to a plasma processing apparatus and a substrate support.

### BACKGROUND

A plasma processing apparatus has a substrate support which supports a substrate to be processed in a plasma processing container in which plasma processing is performed.

A supply hole for supplying a heat transfer gas between a back surface of the substrate placed on the substrate support and a support surface of the substrate support is formed in the substrate support. Abnormal discharge may occur in the supply hole during the plasma processing.

Patent Document 1: Japanese Laid-open Patent Publication No. 2019-220555

### SUMMARY

The present disclosure provides a plasma processing apparatus and a substrate support capable of suppressing abnormal discharge in a heat transfer gas supply hole.

In accordance with an aspect of the present disclosure, there is provided a plasma processing apparatus comprising: a plasma processing container; and a substrate support disposed in the plasma processing container and having a support surface on an upper portion of a base. The substrate support includes: a heat transfer gas supply hole configured to supply a heat transfer gas from the base side to the support surface; a first member disposed on the support surface side in the heat transfer gas supply hole and made of silicon carbide; a second member disposed under the first member in the heat transfer gas supply hole and made of a porous resin; and a third member disposed under the second member in the heat transfer gas supply hole and made of polytetrafluoroethylene (PTFE).

### BRIEF DESCRIPTION OF THE DRAWINGS

FIG. 1 is a diagram showing an example of a plasma processing system according to a first embodiment of the present disclosure.

FIG. 2 is a partially enlarged view showing an example of a cross section of a substrate support according to the first embodiment.

FIG. 3 is a partially enlarged view showing an example of a cross section of a heat transfer gas supply hole according to a reference example.

FIG. 4 is a diagram showing an example of a second member of a rod according to the reference example.

FIG. 5 is a partially enlarged view showing an example of a cross section of a heat transfer gas supply hole according to the first embodiment.

FIG. 6 is a partially enlarged view showing an example of a cross section of a heat transfer gas supply hole according to Modified Example 1.

FIG. 7 is a partially enlarged view showing an example of a cross section of a heat transfer gas supply hole according to Modified Example 2.

FIG. 8 is a partially enlarged view showing an example of a cross section of a heat transfer gas supply hole according to a second embodiment.

### DETAILED DESCRIPTION

Hereinafter, disclosed embodiments of a plasma processing apparatus and a substrate support will be described in detail with reference to the accompanying drawings. The disclosed techniques are not limited by the following embodiments.

In order to suppress abnormal discharge in a heat transfer gas supply hole during plasma processing, it has been proposed to arrange an embedded member, in which irregularities are formed on a surface thereof, in the supply hole. In this case, the heat transfer gas is supplied to a support surface through gaps due to the irregularities. However, when a pressure of the heat transfer gas is increased to cool a substrate placed on the substrate support or an edge ring, abnormal discharge may occur in a gap between the embedded member and the supply hole according to Paschen's law. Therefore, it is expected to suppress the abnormal discharge in the heat transfer gas supply hole even when the pressure of the heat transfer gas is increased.

### First Embodiment

### Configuration of Plasma Processing System

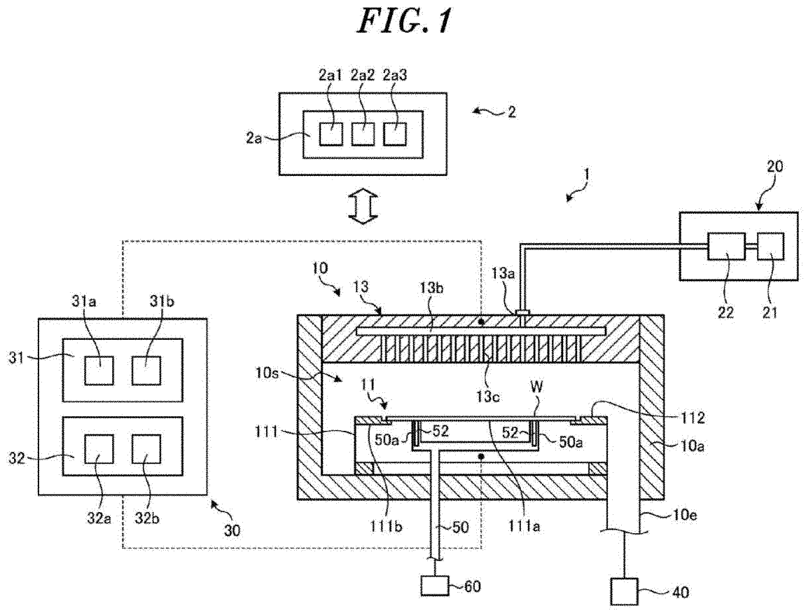

Hereinafter, an example of a configuration of a plasma processing system will be described. FIG. 1 is a diagram showing an example of a plasma processing system according to a first embodiment of the present disclosure. As shown in FIG. 1, the plasma processing system includes a capacitive coupling plasma processing apparatus 1 and a controller 2. The capacitive coupling plasma processing apparatus 1 may include the controller 2. The capacitive coupling plasma processing apparatus 1 includes a plasma processing chamber 10, a gas supply 20, a power source 30, an exhaust system 40, and a heat transfer gas supply 60. Further, the plasma processing apparatus 1 includes a substrate support 11 and a gas introduction part. The gas introduction part is configured to introduce at least one processing gas into the plasma processing chamber 10. The gas introduction part includes a shower head 13. The substrate support 11 is disposed in the plasma processing chamber 10. The shower head is disposed above the substrate support 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas discharge port for discharging the gas from the plasma processing space. The side wall 10a is grounded. The shower head 13 and the substrate support 11 are electrically insulated from a housing of the plasma processing chamber 10.

The substrate support 11 includes a main body 111 and a ring assembly 112. The main body 111 has a central region (a substrate support surface) 111a for supporting a substrate (a wafer) W and an annular region (a ring support surface) 111b for supporting the ring assembly 112. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. In one embodiment, the main body 111 includes a base and an electrostatic chuck. The base includes a conductive member. The conductive member of the base serves as a lower electrode. The electrostatic chuck is disposed on the base. An upper surface of the electrostatic chuck has the substrate support surface 111a. The ring assembly 112 includes one or more annular members. At least one of the one or more annular members is an edge ring. Further, although not shown, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid such as brine and gas flow through the flow path. Further, the substrate support 11 includes the heat transfer gas supply 60 configured to supply a heat transfer gas through a heat transfer gas supply path 50 and a heat transfer gas supply hole 50a between a back surface of the substrate W and the substrate support surface 111a and between the ring assembly 112 and the ring support surface 111b. Further, a rod 52 for suppressing abnormal discharge in the heat transfer gas supply hole 50a is disposed in the heat transfer gas supply hole 50a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 serves as an upper electrode. In addition to the shower head 13, the gas introduction part may include one or more side gas injectors (SGIs) mounted in one or more openings formed in the side wall 10a.

The gas supply 20 may include at least one gas source 21 and at least one flow rate controller 22. In one embodiment, the gas supply 20 is configured to supply at least one processing gas from the corresponding gas source 21 to the shower head 13 via the corresponding flow rate controller 22. Each of the flow rate controllers 22 may include, for example, a mass flow controller or a pressure-controlled flow rate controller. Further, the gas supply 20 may include one or more flow rate modulation devices that modulate or pulse a flow rate of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. Thus, plasma is formed from at least one processing gas supplied to the plasma processing space 10s. Therefore, the RF power source 31 may serve as at least a part of a plasma generator configured to generate plasma from one or more processing gases in the plasma processing chamber 10. Further, a bias potential is generated in the substrate W by supplying the bias RF signal to the conductive member of the substrate support 11, and an ionic component in the formed plasma can be attracted to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit and is configured to generate a source RF signal (source RF power) for plasma generation. In one embodiment, the source RF signal has a frequency in a range of 13 MHz to 150 MHz. In one embodiment, the first RF generator 31a may be configured to generate a plurality of source RF signals with different frequencies. The one or more generated source RF signals are supplied to the conductive member of the substrate support 11 and/or the conductive member of the shower head 13. The second RF generator 31b is coupled to the conductive member of the substrate support 11 via at least one impedance matching circuit and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 31b may be configured to generate a plurality of bias RF signals with different frequencies. The one or more generated bias RF signals are supplied to the conductive member of the substrate support 11. Also, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and is configured to generate a first DC signal. The generated first bias DC signal is applied to the conductive member of the substrate support 11. In one embodiment, the first DC signal may be applied to another electrode such as an electrode in the electrostatic chuck. In one embodiment, the second DC generator 32b is connected to the conductive member of the shower head 13 and is configured to generate a second DC signal. The generated second DC signal is applied to the conductive member of the shower head 13. In various embodiments, at least one of the first and second DC signals may be pulsed. The first and second DC generators 32a and 32b may be provided in addition to the RF power source 31, and the first DC generator 32a may be provided in place of the second RF generator 31b.

The exhaust system 40 may be connected to, for example, a gas discharge port 10e provided at the bottom of the plasma processing chamber 10. The exhaust system 40 may include a pressure adjustment valve and a vacuum pump. The pressure in the plasma processing space 10s is adjusted by the pressure adjustment valve. The vacuum pump may include a turbo molecular pump, a dry pump or a combination thereof.

The heat transfer gas supply 60 supplies a heat transfer gas (gas for cold heat transfer) to the heat transfer gas supply hole 50a provided in the base of the substrate support 11 and the electrostatic chuck via the heat transfer gas supply path 50. As the heat transfer gas, for example, helium gas is used. The heat transfer gas is supplied from the heat transfer gas supply hole 50a of the substrate support surface 111a and the ring support surface 111b between the back surface of the substrate W and the substrate support surface 111a and between the ring assembly 112 and the ring support surface 111b. By supplying the heat transfer gas, the heat is removed from the substrate W and the edge ring, which have become hot due to heat supplied by plasma processing.

The controller 2 processes computer-executable instructions that cause the plasma processing apparatus 1 to perform various steps described in the present disclosure. The controller 2 may be configured to control each element of the plasma processing apparatus 1 to perform the various steps described herein. In one embodiment, a part or all of the controller 2 may be included in the plasma processing apparatus 1. The controller 2 may include, for example, a computer 2a. The computer 2a may include, for example, a central processing unit (CPU) 2a1, a storage part 2a2, and a communication interface 2a3. The CPU 2a1 may be configured to perform various control operations based on a program stored in the storage part 2a2. The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Arrangement of Heat Transfer Gas Supply Hole 50a

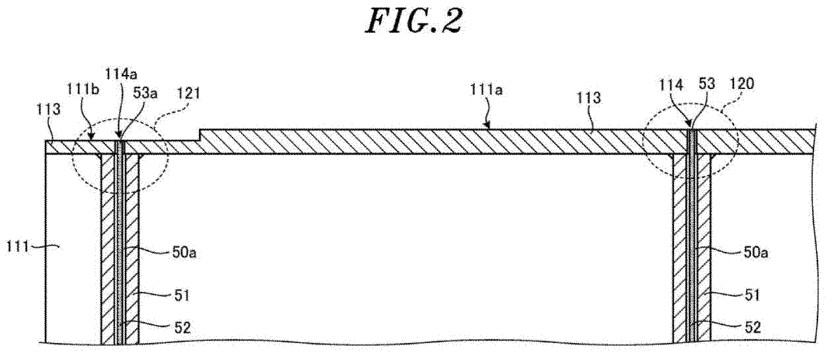

Next, an arrangement of the heat transfer gas supply holes 50a in the substrate support 11 will be described with reference to FIG. 2. FIG. 2 is a partially enlarged view showing an example of a cross section of the substrate support of the first embodiment. As shown in FIG. 2, an electrostatic chuck 113 is provided on an upper portion of the main body 111 of the substrate support 11, and an upper surface of the electrostatic chuck 113 serves as the substrate support surface 111a and the ring support surface 111b. The electrostatic chuck 113 is made of, for example, a ceramic plate. Openings 114 and 114a in the electrostatic chuck 113 constitute the uppermost portion of each of the heat transfer gas supply holes 50a. The heat transfer gas supply holes 50a are configured of sleeves 51 and the openings 114 and 114a of the electrostatic chuck 113, and a plurality of heat transfer gas supply holes 50a are provided in each of the substrate support surface 111a and the ring support surface 111b. The sleeve 51 is made of, for example, alumina (Al₂O₃). FIG. 2 shows a cross section of some of the heat transfer gas supply holes 50a provided in each of the substrate support surface 111a and the ring support surface 111b.

The rod 52 is disposed in each of the heat transfer gas supply holes 50a. Portions of the rods 52 disposed in each of the openings 114 and 114a are configured of first members 53 and 53a. A region 120 of the heat transfer gas supply hole 50a provided in the substrate support surface 111a and a region 121 of the heat transfer gas supply hole 50a provided in the ring support surface 111b have the same configuration except that a thickness of the electrostatic chuck 113 is different, and thus, in the following description, the region 120 will be described as an example.

### Cross Section of Heat Transfer Gas Supply Hole in Reference Example

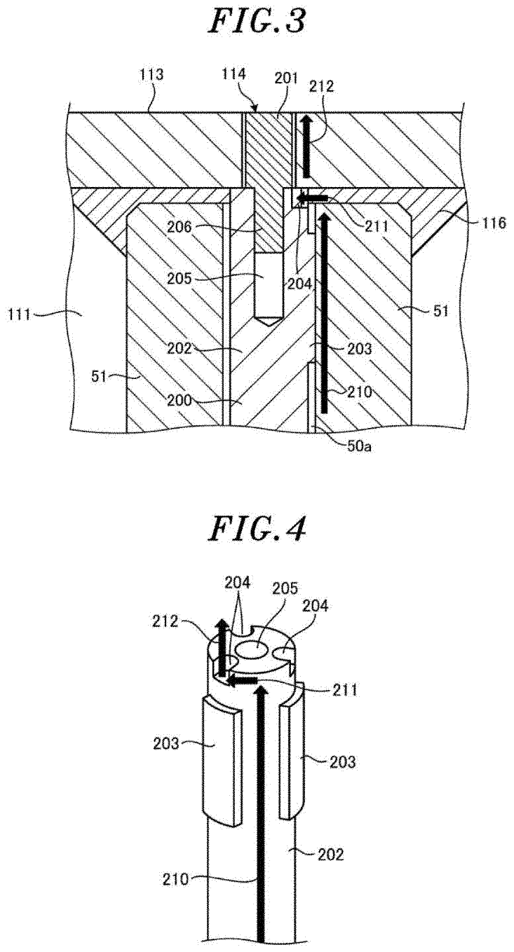

Here, with reference to FIGS. 3 and 4, a cross section of a heat transfer gas supply hole according to a reference example in which an embedded member having irregularities on a surface thereof is disposed in the supply hole will be described. FIG. 3 is a partially enlarged view showing an example of a cross section of the heat transfer gas supply hole of the reference example. FIG. 4 is a diagram showing an example of a second member of a rod of the reference example. As shown in FIGS. 3 and 4, in the reference example, a rod 200 is disposed in the heat transfer gas supply hole 50a instead of the rod 52. Further, the rod 200 has a first member 201 instead of the first member 53, and the first member 201 is connected to a second member 202. The second member 202 has a convex portion 203 for preventing falling, a cutout 204 for transmitting a heat transfer gas, and a hole 205 for inserting the first member 201. The first member 201 is connected to an upper portion of the second member 202 by fitting a protrusion 206 provided at a lower portion thereof into the hole 205.

In the region 120, the opening 114 of the electrostatic chuck 113 is connected via an opening of an adhesive layer 116 at a connection portion with the heat transfer gas supply hole 50a in the sleeve 51 directly below. An inner diameter of the opening 114 which is the uppermost portion of the heat transfer gas supply hole 50a is smaller than an inner diameter of the heat transfer gas supply hole 50a of the sleeve 51. An upper surface of the second member 202 is in contact with a lower surface of the electrostatic chuck 113 to surround an outer peripheral portion of the heat transfer gas supply hole 50a in the lower surface of the electrostatic chuck 113.

In the heat transfer gas supply hole 50a, the heat transfer gas flows in the order of flow paths 210 to 212. The flow path 210 is a gap between the second member 202 and the sleeve 51. The flow path 211 is the cutout 204 connected to the flow path 210. The flow path 212 is a gap between the first member 201 and an inner wall of the opening 114 of the electrostatic chuck 113, which is connected to the cutout 204. In addition, in FIGS. 3 and 4, an arrow is attached in the vicinity of the flow path. In the rod 200 of the reference example, when a pressure of the heat transfer gas is increased, in a gap such as a space in the cutout 204, electrons ionized from helium, which is a heat transfer gas, may be accelerated by receiving a potential difference, and abnormal discharge may occur. That is, the potential difference is likely to occur in the gas flow path in the vicinity of a joint between a ceramic plate of the electrostatic chuck 113 and the sleeve 51 made of alumina, and the abnormal discharge may occur in the gas flow path. Therefore, it is required to suppress the abnormal discharge in an upper portion of the heat transfer gas supply hole 50a.

### Cross Section of Heat Transfer Gas Supply Hole of First Embodiment

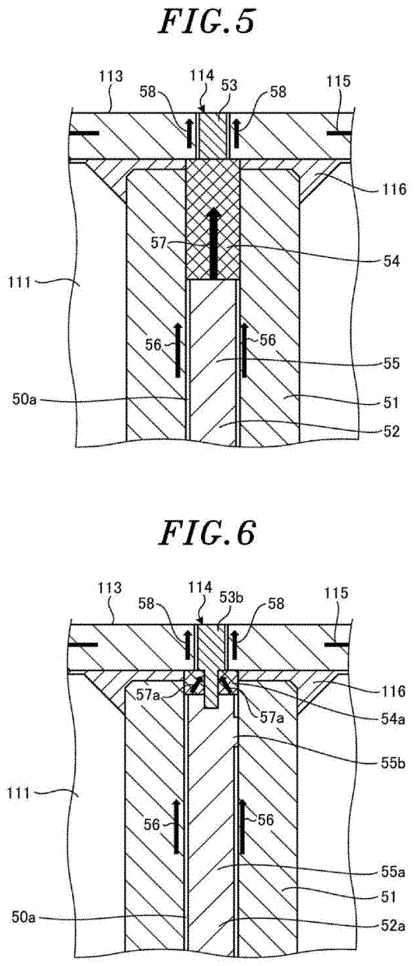

Next, a cross section of the heat transfer gas supply hole in the first embodiment will be described with reference to FIG. 5. FIG. 5 is a partially enlarged view showing an example of the cross section of the heat transfer gas supply hole of the first embodiment. As shown in FIG. 5, in the first embodiment, the cylindrical rod 52 is disposed in the heat transfer gas supply hole 50a. The rod 52 has the first member 53 which is a portion disposed in the opening 114, a second member 54 disposed under the first member 53, and a third member 55 disposed under the second member 54. FIG. 5 also shows a part of an electrode 115 provided inside the electrostatic chuck 113.

The first member 53 is made of silicon carbide (SiC) and has a gap between the first member 53 and the inner wall of the heat transfer gas supply hole 50a (an inner wall of the opening 114) in the electrostatic chuck 113. The gap is, for example, in a range of 0.01 mm to 0.4 mm. Further, a length of the first member 53 is at least a length corresponding to a thickness of the electrostatic chuck 113. The first member 53 relieves the potential difference in the vicinity of the opening 114 of the electrostatic chuck 113. The first member 53 may be another ceramic such as alumina (Al₂O₃). The second member 54 is made of a porous resin and is in contact with the inner wall of the heat transfer gas supply hole 50a inside the sleeve 51 and on the lower surface of the electrostatic chuck 113 so as not to have a gap therebetween. The porous resin is a resin having a porous structure, and for example, a resin such as polyimide (PI), PTFE, polychlorotrifluoroethylene (PCTFE), perfluoroalkoxyalkane resin (PFA), polyetheretherketone (PEEK), polyetherimide (PEI), POM (polyoxymethylene, polyacetal, polyformaldehyde), methyl cellulose (MC), polycarbonate (PC), or polyphenylene sulfone (PPS) may be used. For example, PTFE is preferably used as the porous resin. There may be a small gap between the second member 54 and the inner wall of the heat transfer gas supply hole 50a, and the second member 54 having a diameter larger than the inner diameter of the heat transfer gas supply hole 50a may be press-fitted. That is, the gap between the second member 54 and the inner wall of the heat transfer gas supply hole 50a may be, for example, in a range of −0.2 mm to +0.2 mm.

In the region 120 of the first embodiment, as in the reference example, the opening 114 of the electrostatic chuck 113 is connected via the opening of the adhesive layer 116 at the connection portion with the heat transfer gas supply hole 50a in the sleeve 51 directly below. The inner diameter of the opening 114 which is the uppermost portion of the heat transfer gas supply hole 50a is smaller than the inner diameter of the heat transfer gas supply hole 50a of the sleeve 51. The upper surface of the second member 54 is in contact with the lower surface of the electrostatic chuck 113 so as not to have a gap therebetween to surround the outer peripheral portion of the heat transfer gas supply hole 50a in the lower surface of the electrostatic chuck 113.

The third member 55 is made of a resin, for example, PTFE, and is disposed inside the sleeve 51 to have a gap between the third member 55 and the inner wall of the heat transfer gas supply hole 50a. The gap is, for example, in a range of 0.01 mm to 0.6 mm. As shown in FIG. 5, the rod 52 is in a state in which the first member 53, the second member 54, and the third member 55 are in contact with each other in this order from the upper surface side of the electrostatic chuck 113. That is, a lower surface of the first member 53 is in contact with an upper surface of the second member 54, and a lower surface of the second member 54 is in contact with an upper surface of the third member 55. In the rod 52, the first member 53 and the second member 54 may not be adhered to each other. Further, in the rod 52, the second member 54 and the third member 55 are adhered to each other, but when the convex portion for preventing falling is provided in the third member 55, the second member 54 and the third member 55 may not be adhered to each other. The rod 52 is not adhered to the heat transfer gas supply hole 50a, but the second member 54 and the third member 55 are fixed inside the heat transfer gas supply hole 50a.

In the heat transfer gas supply hole 50a, the heat transfer gas flows in the order of the flow paths 56 to 58. The flow path 56 is a gap between the third member 55 and the sleeve 51. The flow path 57 is a flow path that passes through the porous structure inside the second member 54, which is connected to the flow path 56. The flow path 58 is a gap between the first member 53 and the inner wall of the opening 114 of the electrostatic chuck 113, which is connected to the flow path 57. In FIG. 5, an arrow is attached in the vicinity of the flow path to indicate a flow of the heat transfer gas. That is, in the first embodiment, the heat transfer gas is supplied to the substrate support surface 111a through the gap between the third member 55 and the inner wall of the heat transfer gas supply hole 50a (the sleeve 51), the inside of the second member 54, and the gap between the first member 53 and the inner wall of the heat transfer gas supply hole 50a (the inside of the opening 114). In the rod 52, even when the pressure of the heat transfer gas is increased, since there is no space on the lower surface of the electrostatic chuck 113 and near the upper portion of the sleeve 51 and electrons do not travel straight, the acceleration of the electrons is suppressed, and thus the abnormal discharge in the heat transfer gas supply hole 50a can be suppressed. That is, since the first member 53 and the sleeve 51 are not directly exposed to each other by sandwiching the second member 54 which is a porous resin between the first member 53 made of silicon carbide (SiC) and the sleeve 51 made of alumina (Al₂O₃), the abnormal discharge in the heat transfer gas supply hole 50a can be suppressed.

### Modified Example 1

Next, Modified Example 1 in which a structure of the upper portion of the rod 52 is changed will be described with reference to FIG. 6. FIG. 6 is a partially enlarged view showing an example of a cross section of a heat transfer gas supply hole according to Modified Example 1. Since a configuration of a part of the plasma processing apparatus in Modified Example 1 is the same as that of the first embodiment described above, the description of the overlapping configurations and operations will be omitted.

As shown in FIG. 6, in Modified Example 1, a rod 52a is disposed inside the heat transfer gas supply hole 50a. The rod 52a has a first member 53b which is a portion disposed in the opening 114, a second member 54a disposed under the first member 53b, and a third member 55a disposed under the second member 54a.

Like the first member 53, the first member 53b is made of silicon carbide (SiC) and has a gap between the first member 53b and the inner wall of the heat transfer gas supply hole 50a (the inner wall of the opening 114) in the electrostatic chuck 113. The gap is, for example, in a range of 0.01 mm to 0.4 mm. Further, a lower portion of the first member 53b extends to the inside of the sleeve 51, passes through the second member 54a and is fixed to an upper portion of the third member 55a. The second member 54a is made of a porous resin and is in contact with the inner wall of the heat transfer gas supply hole 50a inside the sleeve 51 and on the lower surface of the electrostatic chuck 113 so as not to have a gap. A space between the second member 54a and the inner wall of the heat transfer gas supply hole 50a may be, for example, in the range of −0.2 mm to +0.2 mm, as in the first embodiment. The second member 54a is shorter than the second member 54 in a lengthwise direction (a longitudinal direction), and the lower portion of the first member 53b passes through a center of the second member 54a. The second member 54a is in contact with the side surface of the first member 53b passing there through so as not to have a gap therebetween. As in the first embodiment, the upper surface of the second member 54a is in contact with the lower surface of the electrostatic chuck 113 so as not to have a gap therebetween to surround the outer peripheral portion of the heat transfer gas supply hole 50a in the lower surface of the electrostatic chuck 113.

The third member 55a is made of a resin, for example, PTFE and is disposed in the sleeve 51 to have a gap between the third member 55a and the inner wall of the heat transfer gas supply hole 50a. The gap is, for example, in a range of 0.01 mm to 0.6 mm. The third member 55a has a convex portion 55b for preventing falling. Further, the lower portion of the first member 53b is fitted and fixed into the upper portion of the third member 55a. As shown in FIG. 6, in the rod 52a, the first member 53b, the second member 54a and the third member 55a are in contact with each other in this order from the upper surface side of the electrostatic chuck 113. The rod 52a is in a state in which the first member 53b is fixed to the third member 55a via the second member 54a, and the first member 53b, the second member 54a, and the third member 55a are integrated.

In the heat transfer gas supply hole 50a of Modified Example 1, the heat transfer gas flows in the order of the flow path 56, the flow path 57a, and the flow path 58. The flow path 56 is a gap between the third member 55a and the sleeve 51. The flow path 57a is a flow path that passes through the porous structure inside the second member 54a, which is connected to the flow path 56. The flow path 57a is shorter than the flow path 57 so that the heat transfer gas can easily flow. That is, the flow path 57a is a flow path having a higher conductance than the flow path 57. A length of the second member 54a can be determined by a trade-off between the conductance and the suppression of the abnormal discharge. The flow path 58 is a gap between the first member 53b and the inner wall of the opening 114 of the electrostatic chuck 113, which is connected to the flow path 57a. In FIG. 6, an arrow is attached in the vicinity of the flow path to indicate the flow of the heat transfer gas. That is, in Modified Example 1, the heat transfer gas is supplied to the substrate support surface 111a through the gap between the third member 55a and the inner wall of the heat transfer gas supply hole 50a (the sleeve 51), the inside of the second member 54a, and the gap between the first member 53b and the inner wall of the heat transfer gas supply hole 50a (inside the opening 114).

In the rod 52a, even when the pressure of the heat transfer gas is increased, since there is no space on the lower surface of the electrostatic chuck 113 and near the upper portion of the sleeve 51 and electrons do not travel straight, the acceleration of the electrons is suppressed, and thus the abnormal discharge in the heat transfer gas supply hole 50a can be suppressed. Further, since a distance through which the heat transfer gas flows through the second member 54a made of the porous resin is short, the conductance of the heat transfer gas supply hole 50a can be made larger than that in the rod 52 of the first embodiment.

### Modified Example 2

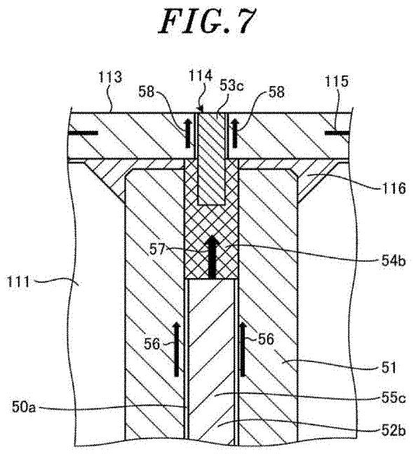

Next, Modified Example 2 in which a structure of the upper portion of the rod 52 is changed will be described with reference to FIG. 7. FIG. 7 is a partially enlarged view showing an example of a cross section of a heat transfer gas supply hole according to Modified Example 2. Since a configuration of a part of the plasma processing apparatus in Modified Example 2 is the same as that of the first embodiment described above, the description of the overlapping configurations and operations will be omitted.

As shown in FIG. 7, in Modified Example 2, a rod 52b is disposed inside the heat transfer gas supply hole 50a. The rod 52b includes a first member 53c which is a portion disposed in the opening 114, a second member 54b disposed under the first member 53c, and a third member 55c disposed under the second member 54b.

Like the first member 53, the first member 53c is made of silicon carbide (SiC) and has a gap between the first member 53c and the inner wall of the heat transfer gas supply hole 50a (the inner wall of the opening 114) in the electrostatic chuck 113. The gap is, for example, in a range of 0.01 mm to 0.4 mm. Further, a lower portion of the first member 53c extends into the sleeve 51 and is fitted and fixed into an upper portion of the second member 54b. The second member 54b is made of a porous resin and is in contact with the inner wall of the heat transfer gas supply hole 50a inside the sleeve 51 and on the lower surface of the electrostatic chuck 113 so as not to have a gap. A gap between the second member 54b and the inner wall of the heat transfer gas supply hole 50a can be, for example, in the range of −0.2 mm to +0.2 mm, as in the first embodiment. A hole for fitting the lower portion of the first member 53c is provided in the upper portion of the second member 54b as compared with the second member 54. As in the first embodiment, an upper surface of the second member 54b is in contact with the lower surface of the electrostatic chuck 113 so as to surround the outer peripheral portion of the heat transfer gas supply hole 50a in the lower surface of the electrostatic chuck 113 so as not to have a gap.

The third member 55c is made of a resin, for example, PTFE and is disposed inside the sleeve 51 so as to have a gap between the third member 55c and the inner wall of the heat transfer gas supply hole 50a. The gap is, for example, in a range of 0.01 mm to 0.6 mm. A lower portion of the second member 54b is fixed to an upper portion of the third member 55c by adhesion or the like. As shown in FIG. 7, in the rod 52b, the first member 53c, the second member 54b, and the third member 55c are in contact with each other in this order from the upper surface side of the electrostatic chuck 113.

In the heat transfer gas supply hole 50a of Modified Example 2, the heat transfer gas flows in the order of the flow paths 56 to 58. The flow path 56 is a gap between the third member 55c and the sleeve 51. The flow path 57 is a flow path that passes through the porous structure inside the second member 54b, which is connected to the flow path 56. The flow path 58 is a gap between the first member 53c and the inner wall of the opening 114 of the electrostatic chuck 113, which is connected to the flow path 57. In FIG. 7, an arrow is attached in the vicinity of the flow path to indicate the flow of the heat transfer gas. That is, in Modified Example 2, the heat transfer gas is supplied to the substrate support surface 111a through the gap between the third member 55c and the inner wall of the heat transfer gas supply hole 50a (the sleeve 51), the inside of the second member 54b, and the gap between the first member 53c and the inner wall of the heat transfer gas supply hole 50a (inside the opening 114).

In the rod 52b, even when the pressure of the heat transfer gas is increased, since there is no space on the lower surface of the electrostatic chuck 113 and near the upper portion of the sleeve 51, and electrons do not travel straight, the acceleration of the electrons is suppressed, and thus the abnormal discharge in the heat transfer gas supply hole 50a can be suppressed.

### Second Embodiment

In the first embodiment described above, although the first member (53, 53a, 53b, and 53c) made of silicon carbide (SiC) is provided inside the opening 114 of the electrostatic chuck 113, a porous member may be provided inside the opening 114 of the electrostatic chuck 113, and an embodiment in this case will be described as a second embodiment. The same reference numerals are assigned to the same configurations as those of the plasma processing apparatus 1 of the first embodiment and the description of the overlapping configurations and operations will be omitted.

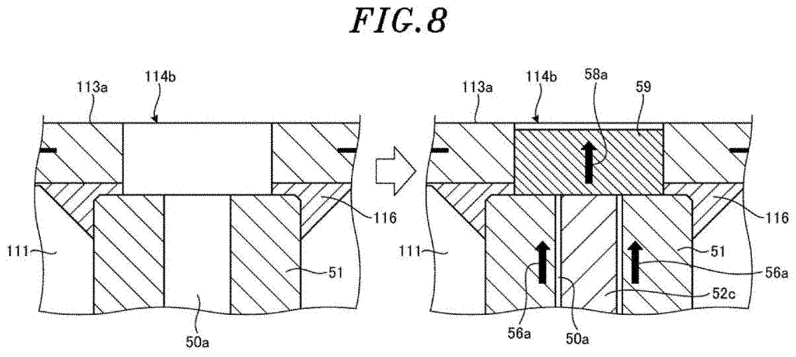

FIG. 8 is a partially enlarged view showing an example of a cross section of a heat transfer gas supply hole according to the second embodiment. As shown in FIG. 8, in the second embodiment, an opening above the sleeve 51, that is, an opening 114b, having a diameter larger than the inner diameter of the heat transfer gas supply hole 50a in the sleeve 51 is provided in the electrostatic chuck 113a. The opening 114b is formed, for example, by spot facing. Further, an opening having the same diameter as the opening 114b is also provided in the adhesive layer 116. In the second embodiment, a rod 52c is provided inside the heat transfer gas supply hole 50a of the sleeve 51 so that an upper end of the sleeve 51 and an upper end of the rod 52c are at the same height. Next, a porous member 59 is inserted into the opening 114b from the upper surface side of the electrostatic chuck 113a and is adhered to upper surfaces of the sleeve 51 and the rod 52c. An adhesive is not adhered to a portion corresponding to a gap between the sleeve 51 and the rod 52c. Further, the rod 52c having the porous member 59 adhered to the upper surface thereof in advance may be inserted into the heat transfer gas supply hole 50a. In this case, the rod 52c and the porous member 59 can be fixed without using an adhesive by press-fitting the porous member 59 with a diameter larger than the diameter of the opening 114b.

A side surface of the porous member 59 is in contact with the opening 114b and an inner wall of the opening of the adhesive layer 116 so as not to have a gap. Further, a lower surface of the porous member 59 is in contact with the upper surface of the sleeve 51 and the rod 52c so as not to have a gap. The porous member 59 is made of, for example, a porous resin, like the second member 54 of the first embodiment.

Like the third member 55 of the first embodiment, the rod 52c is made of a resin, for example, PTFE and is disposed inside the sleeve 51 to have a gap between the rod 52c and the inner wall of the heat transfer gas supply hole 50a.

In the heat transfer gas supply hole 50a of the second embodiment, the heat transfer gas flows in the order of flow paths 56a and 58a. The flow path 56a is a gap between the rod 52c and the sleeve 51. The flow path 58a is a flow path that passes through the porous structure inside the porous member 59, which is connected to the flow path 56a. In FIG. 8, an arrow is attached in the vicinity of the flow path to indicate the flow of the heat transfer gas. That is, in the second embodiment, the heat transfer gas is supplied to the substrate support surface 111a through the gap between the rod 52c and the inner wall of the heat transfer gas supply hole 50a (the sleeve 51) and the inside of the porous member 59. In the rod 52c, even when the pressure of the heat transfer gas is increased, since there is no space on the lower surface of the electrostatic chuck 113 and near the upper portion of the sleeve 51 and electrons do not travel straight, the acceleration of the electrons is suppressed, and thus the abnormal discharge in the heat transfer gas supply hole 50a can be suppressed.

As described above, according to the first embodiment, the plasma processing apparatus 1 includes a plasma processing container (the plasma processing chamber 10), and a substrate support 11 disposed in the plasma processing container and having a support surface (the substrate support surface 111a and the ring support surface 111b) on the upper portion of the base. The substrate support 11 includes the heat transfer gas supply hole 50a that supplies a heat transfer gas from the base side to the support surface, the first member 53 (53a, 53b, and 53c) disposed on the support surface side in the heat transfer gas supply hole 50a and made of silicon carbide, the second member 54 (54a and 54b) disposed under the first member 53 (53a, 53b, and 53c) in the heat transfer gas supply hole 50a and made of a porous resin, and the third member 55 (55a and 55c) disposed under the second member 54 (54a and 54b) in the heat transfer gas supply hole 50a and made of PTFE. As a result, the abnormal discharge in the heat transfer gas supply hole 50a can be suppressed.

Further, according to the first embodiment, the second member 54 (54a and 54b) is disposed so as not to have a gap between the second member 54 (54a and 54b) and the inner wall of the heat transfer gas supply hole 50a. As a result, the heat transfer gas can flow inside the second member 54 (54a and 54b).

Further, according to the first embodiment, the length of the first member 53 (53a, 53b, and 53c) is at least a length corresponding to the thickness of the ceramic plate (the electrostatic chuck 113) provided on the support surface in the heat transfer gas supply holes 50a. As a result, the potential difference can be relieved, and the abnormal discharge in the heat transfer gas supply hole 50a can be suppressed.

Further, according to the first embodiment, the ceramic plate is the electrostatic chuck 113 having an electrode therein. As a result, the abnormal discharge in the heat transfer gas supply hole 50a can be suppressed.

Further, according to the first embodiment, the heat transfer gas supply hole 50a is configured so that the inner diameter in the ceramic plate is smaller than the inner diameter in the base (the sleeve 51), and the upper surface of the second member 54 (54a and 54b) is in contact with the lower surface of the ceramic plate so as to surround the outer peripheral portion of the heat transfer gas supply hole 50a in the lower surface of the ceramic plate. As a result, the abnormal discharge in the heat transfer gas supply hole 50a can be suppressed.

Further, according to the first embodiment, the first member 53 (53a, 53b, and 53c) is disposed to have a gap between the first member 53 (53a, 53b, and 53c) and the inner wall of the heat transfer gas supply hole 50a. As a result, the heat transfer gas that has passed through the second member 54 (54a and 54b) can be supplied to the support surface of the substrate support 11.

Further, according to the first embodiment, the third member 55 (55a and 55c) is disposed to have a gap between the third member 55 (55a and 55c) and the inner wall of the heat transfer gas supply hole 50a. As a result, the heat transfer gas can flow to the second member 54 (54a and 54b).

Further, according to the first embodiment, the heat transfer gas is supplied to the support surface through the gap between the third member 55 (55a and 55c) and the inner wall of the heat transfer gas supply hole 50a, the inside of the second member 54 (54a and 54b) and the gap between the first member 53 (53a, 53b, and 53c) and the inner wall of the heat transfer gas supply hole 50a. As a result, the abnormal discharge in the heat transfer gas supply hole 50a can be suppressed.

Further, according to the first embodiment, the lower surface of the first member 53 is in contact with the upper surface of the second member 54, and the lower surface of the second member 54 is in contact with the upper surface of the third member 55. As a result, the abnormal discharge in the heat transfer gas supply hole 50a can be suppressed.

Further, according to Modified Example 1, the lower portion of the first member 53b passes through the second member 54a and is fixed to the upper portion of the third member 55a. As a result, a flow rate of the heat transfer gas can be increased while the abnormal discharge in the heat transfer gas supply hole 50a is suppressed.

Further, according to Modified Example 2, the lower portion of the first member 53c is fixed to the inside of the second member 54b. As a result, the abnormal discharge in the heat transfer gas supply hole 50a can be suppressed.

Further, according to the first embodiment, the porous resin is PI, PTFE, PCTFE, PFA, PEEK, PEI, POM, MC, PC, or PPS. As a result, the heat transfer gas can be supplied to the support surface of the substrate support 11 while the abnormal discharge in the heat transfer gas supply hole 50a is suppressed.

Each of the above embodiments should be considered to be exemplary in all respects and not restrictive. Each of the above embodiments may be omitted, replaced or modified in various ways without departing from the scope of the appended claims and the gist thereof.

Further, in each of the above embodiments, although the capacitive coupling plasma processing apparatus 1 that performs processing such as etching on the substrate W using capacitive coupling plasma as a plasma source has been described as an example, the disclosed technique is not limited thereto. As long as it is a device that processes the substrate W using plasma, the plasma source is not limited to the capacitive coupling plasma, and any plasma source such as inductive coupling plasma, microwave plasma, or magnetron plasma can be used.

1. A plasma processing apparatus comprising:
a plasma processing container; and
a substrate support disposed in the plasma processing container and having a support surface on an upper portion of a base,
wherein the substrate support includes:
a heat transfer gas supply hole configured to supply a heat transfer gas from the base side to the support surface;
a first member disposed on the support surface side in the heat transfer gas supply hole and made of silicon carbide;
a second member disposed under the first member in the heat transfer gas supply hole and made of a porous resin; and
a third member disposed under the second member in the heat transfer gas supply hole and made of polytetrafluoroethylene (PTFE).

2. The plasma processing apparatus of claim 1, wherein the second member is disposed so as not to have a gap between the second member and an inner wall of the heat transfer gas supply hole.

3. The plasma processing apparatus of claim 1, wherein a length of the first member is at least a length corresponding to a thickness of a ceramic plate provided on the support surface in the heat transfer gas supply hole.

4. The plasma processing apparatus of claim 3, wherein the ceramic plate is an electrostatic chuck having an electrode therein.

5. The plasma processing apparatus of claim 3, wherein the heat transfer gas supply hole is configured so that an inner diameter in the ceramic plate is smaller than an inner diameter in the base, and
an upper surface of the second member is in contact with a lower surface of the ceramic plate to surround an outer peripheral portion of the heat transfer gas supply hole in the lower surface of the ceramic plate.

6. The plasma processing apparatus of claim 1, wherein the first member is disposed to have a gap between the first member and an inner wall of the heat transfer gas supply hole.

7. The plasma processing apparatus of claim 1, wherein the third member is disposed to have a gap between the third member and an inner wall of the heat transfer gas supply hole.

8. The plasma processing apparatus of claim 7, wherein the heat transfer gas is supplied to the support surface through the gap between the third member and the inner wall of the heat transfer gas supply hole, an inside of the second member, and a gap between the first member and the inner wall of the heat transfer gas supply hole.

9. The plasma processing apparatus of claim 1, wherein a lower surface of the first member is in contact with an upper surface of the second member, and
a lower surface of the second member is in contact with an upper surface of the third member.

10. The plasma processing apparatus of claim 1, wherein a lower portion of the first member passes through the second member and is fixed to an upper portion of the third member.

11. The plasma processing apparatus of claim 1, wherein a lower portion of the first member is fixed to an inside of the second member.

12. The plasma processing apparatus of claim 1, wherein the porous resin is polyimide (PI), PTFE, polychlorotrifluoroethylene (PCTFE), perfluoroalkoxyalkane resin (PFA), polyetheretherketone (PEEK), polyetherimide (PEI), POM (polyoxymethylene, polyacetal, polyformaldehyde), methyl cellulose (MC), polycarbonate (PC), or polyphenylene sulfone (PPS).

13. A substrate support which is disposed in a plasma processing container and has a support surface on an upper portion of a base, comprising:
a heat transfer gas supply hole configured to supply a heat transfer gas from the base side to the support surface;
a first member disposed on the support surface side in the heat transfer gas supply hole and made of silicon carbide;
a second member disposed under the first member in the heat transfer gas supply hole and made of a porous resin; and
a third member disposed under the second member in the heat transfer gas supply hole and made of polytetrafluoroethylene (PTFE).

14. The substrate support of claim 13, wherein the second member is disposed so as not to have a gap between the second member and an inner wall of the heat transfer gas supply hole.

15. The substrate support of claim 13, wherein a length of the first member is at least a length corresponding to a thickness of a ceramic plate provided on the support surface in the heat transfer gas supply hole.

16. The substrate support of claim 15, wherein the ceramic plate is an electrostatic chuck having an electrode therein.

17. The substrate support of claim 15, wherein the heat transfer gas supply hole is configured so that an inner diameter in the ceramic plate is smaller than an inner diameter in the base, and
an upper surface of the second member is in contact with a lower surface of the ceramic plate to surround an outer peripheral portion of the heat transfer gas supply hole in the lower surface of the ceramic plate.

18. The substrate support of claim 13, wherein the first member is disposed to have a gap between the first member and an inner wall of the heat transfer gas supply hole.

19. The substrate support of claim 13, wherein the third member is disposed to have a gap between the third member and an inner wall of the heat transfer gas supply hole.

20. The substrate support of claim 19, wherein the heat transfer gas is supplied to the support surface through the gap between the third member and the inner wall of the heat transfer gas supply hole, an inside of the second member, and a gap between the first member and the inner wall of the heat transfer gas supply hole.

21. The substrate support of claim 13, wherein a lower surface of the first member is in contact with an upper surface of the second member, and
a lower surface of the second member is in contact with an upper surface of the third member.

22. The substrate support of claim 13, wherein a lower portion of the first member passes through the second member and is fixed to an upper portion of the third member.

23. The substrate support of claim 13, wherein a lower portion of the first member is fixed to an inside of the second member.

24. The substrate support of claim 13, wherein the porous resin is polyimide (PI), PTFE, polychlorotrifluoroethylene (PCTFE), perfluoroalkoxyalkane resin (PFA), polyetheretherketone (PEEK), polyetherimide (PEI), POM (polyoxymethylene, polyacetal, polyformaldehyde), methyl cellulose (MC), polycarbonate (PC), or polyphenylene sulfone (PPS).
